(19) United States
(12) Patent Application Publication
(10) Pub. No.: US 2011/0186946 A1
(43) Pub. Date: Aug. 4, 2011

(54) Magnetic Tunnel Junction with Domain Wall Pinning

(75) Inventors: Xiaochun Zhu, San Diego, CA (US); Xia Li, San Diego, CA (US); Seung H. Kang, San Diego, CA (US)

(73) Assignee: QUALCOMM INCORPORATED, San Diego, CA (US)

(21) Appl. No.: 12/699,919

(22) Filed: Feb. 4, 2010

(51) Int. Cl. H01L 29/82; H01L 21/30

(52) U.S. Cl. 257/421; 438/3; 257/E29.323; 257/E21.211

(57) ABSTRACT

Magnetic tunnel junctions (MTJs) are manufactured having pinning sites in a ferromagnetic layer of the MTJ. The pinning sites are created using patterns in the photomask used during patterning of the ferromagnetic layer without adding additional processes to manufacturing of the MTJs. The pinning sites create energy barriers substantially preventing a domain wall in the ferromagnetic layer from passing into fixed regions of the ferromagnetic layer. Additionally, the pinning sites substantially prevent a domain wall in the ferromagnetic layer from returning to the middle of the free region. Pinning the domain wall at the boundary of the fixed region and the free region the ferromagnetic layer improves reliability and sensitivity of the MTJ. The ferromagnetic layer may be magnetized in a direction perpendicular to the plane of the ferromagnetic layer.

### TECHNICAL FIELD

The present disclosure generally relates to memory devices. More specifically, the present disclosure relates to magnetic random access memory (MRAM).

### BACKGROUND

FIG. 1A is a schematic illustrating a conventional cell of a magnetic random access memory (MRAM) device. A cell 100 includes a magnetic tunnel junction (MTJ) having a free region 122 coupled between fixed regions 120, 124. A ferromagnetic layer 114 spans regions 120, 122, 124. Additionally, a pinning layer 112 may be coupled to the fixed region 120 of the ferromagnetic layer 114. A reference layer 116 may be coupled to a free region 122 of the ferromagnetic layer 114 through a tunnel barrier layer 118. A pinning layer 110 may be coupled to the fixed region 124 of the ferromagnetic layer 114. The cell 100 is coupled within an MRAM device by access transistors 130, 132 coupled to the pinning layers 112, 110, respectively. The transistors 130, 132 are also coupled to bitline, BL, and bitline bar, /BL, respectively. Gates of the transistors 130, 132 are coupled to a wordline, WL. The reference layer 116 may be coupled to ground or the source line.

The cell 100 generally is programmed in one of two states, “1” or “0”, determined by a magnetization of the free region 122 of the ferromagnetic layer 114 with reference to a magnetization of the reference layer 116. The “1” and “0” states will be described with reference to FIGS. 1B and 1C. Although logical “0” and logical “1” are referred to, one skilled in the art appreciates that the logical values can be switched, with the remainder of the circuit adjusted accordingly, without affecting operation of the cell 100.

FIG. 1B is a cross-sectional view illustrating a conventional cell of a magnetic random access memory device in a “1” state. The cell 100 of FIG. 1B includes a portion of the ferromagnetic layer 114 in the fixed region 120 magnetized up. Another portion of the ferromagnetic layer 114 in the fixed region 124 is magnetized down, and yet another portion of the ferromagnetic layer 114 in the free region 122 is magnetized down.

Sensing in the cell 100 occurs by passing a sense current from both of the fixed regions 112, 110 through the reference layer 116. For example, when a sense current is passed through the pinning layer 112, the fixed region 120 of the ferromagnetic layer 114, the free region 122 of the ferromagnetic layer 114, the tunneling barrier 118, and the reference layer 116, a high resistance state is encountered because the magnetization of the portion of the ferromagnetic layer 114 in the free region 122 is opposite of the reference layer 116. Additionally, sense current is passed through the pinning layer 110, the fixed region 124 of the ferromagnetic layer 114, the free region 122 of the ferromagnetic layer 114, the tunneling barrier 118, and the reference layer 116.

FIG. 1C is a cross-sectional view illustrating a conventional cell of a magnetic random access memory device in a “0” state. The cell 100 of FIG. 1C includes a portion of the ferromagnetic layer 114 in the fixed region 120 magnetized up. Another portion of the ferromagnetic layer 114 in the fixed region 124 is magnetized down, and yet another portion of the ferromagnetic layer 114 in the free region 122 is magnetized up.

When a sensing current is passed through the pinning layer 112, the fixed region 120 of the ferromagnetic layer 114, the free region 122 of the ferromagnetic layer 114, the tunneling barrier 118, and the reference layer 116, a low resistance state is encountered because the magnetization of the portion of the ferromagnetic layer 114 in the free region 122 is parallel with the reference layer 116. Additionally, sense current is passed through the pinning layer 110, the fixed region 124 of the ferromagnetic layer 114, the free region 122 of the ferromagnetic layer 114, the tunneling barrier 118, and the reference layer 116.

Writing a “1” or “0” into the cell 100 occurs by passing a write current through the pinning layer 112, fixed region 120 of the ferromagnetic layer 114, the free region 122 of the ferromagnetic layer 114, the fixed region 124 of the ferromagnetic layer 114, and the pinning layer 110. At a boundary between one of the fixed regions 120, 124 of the ferromagnetic layer 114 with the free region 122 of the ferromagnetic layer 114 a domain wall exists where the magnetization rotates (e.g., between an up and down magnetization). During writing of a “0”, this domain wall is pushed by spin torque current from a boundary 152 between the fixed region 120 of the ferromagnetic layer 114 and the free region 122 of the ferromagnetic layer 114 to a boundary 154 between the free region 122 of the ferromagnetic layer 114 and the fixed region 124 of the ferromagnetic layer 114.

For example, in FIG. 1B a domain wall exists at the boundary 152 between the fixed region 120 of the ferromagnetic layer 114 and the free region 122 of the ferromagnetic layer 114 where the magnetization rotates from up in the fixed region 120 of the ferromagnetic layer 114 to down in the free region 122 of the ferromagnetic layer 114. For another example, in FIG. 1C a domain wall exists at the boundary 154 between the free region 122 of the ferromagnetic layer 114 and the fixed region 124 of the ferromagnetic layer 114 where the magnetization rotates from up in the free region 122 of the ferromagnetic layer 114 to down in the fixed region 124 of the ferromagnetic layer 114.

A write current passed from the fixed region 120 of the ferromagnetic layer 114 to the fixed region 124 of the ferromagnetic layer 114 pushes the domain wall to the boundary 152 resulting in the “1” state of FIG. 1B. A write current passed from the fixed region 124 of the ferromagnetic layer 114 to the fixed region 120 of the ferromagnetic layer 114 pushes the domain wall to the boundary 154 resulting in the “0” state of FIG. 1C. However, the write processes do not always result in the domain wall being located at the boundaries 152, 154.

FIG. 2 is a top-down view illustrating a conventional cell of a magnetic random access memory device with a domain wall dividing the cell. Due to variations in manufacturing processes, the domain wall may be located at a boundary 156 within a portion of the ferromagnetic layer 114 in the fixed region 120 of the ferromagnetic layer 114. Alternatively, the domain wall may be located in the free region 122 of the ferromagnetic layer 114. Domains walls located outside the boundaries 152, 154 result in poor sensitivity and unreliable behavior.

Some pinning sites may exist in the ferromagnetic layer 114 resulting from manufacturing processes and other deviations from ideal such as defects and undesired microcrystalline structures in the ferromagnetic layer 114. These pinning sites may create energy barriers for motion of a domain wall. To minimize total energy in the ferromagnetic layer 114 a domain wall relaxes to the energy barrier. A pinning site located outside the boundaries 152, 154, results in the free region 122 of the ferromagnetic layer 114 not having a uniform magnetization. Consequently, reduced sensitivity and reliability of the cell 100 occurs.

Thus, there is a need for a magnetic random access memory cell with better reliability and higher sensitivity.

### BRIEF SUMMARY

According to one aspect of the disclosure, a magnetic tunnel junction (MTJ) device includes a first fixed region of a ferromagnetic layer. The MTJ device also includes a second fixed region of the ferromagnetic layer. The MTJ device further includes a free region of the ferromagnetic layer between the first fixed region of the ferromagnetic layer and the second fixed region of the ferromagnetic layer. The MTJ device also includes at least one feature in proximity to a first boundary between the first fixed region of the ferromagnetic layer and the free region of the ferromagnetic layer. The MTJ device further includes at least one feature in proximity to a second boundary between the second fixed region of the ferromagnetic layer and the free region of the ferromagnetic layer. The features act as artificial pinning sites for domain walls.

According to a further aspect of the disclosure, a method of manufacturing a magnetic tunnel junction (MTJ) having a first fixed region, a second fixed region, and a free region coupled between the first fixed region and the second fixed region includes patterning a ferromagnetic layer of the MTJ such that the ferromagnetic layer is narrower in a first portion proximate to a boundary between the first fixed region and the free region and such that the ferromagnetic layer is narrower in a second portion proximate to a boundary between the second fixed region and the free region.

According to another aspect of the disclosure, a method of manufacturing a magnetic tunnel junction (MTJ) having a first fixed region, a second fixed region, and a free region coupled between the first fixed region and the second fixed region includes the step of patterning a ferromagnetic layer of the MTJ such that the ferromagnetic layer is narrower in a first portion proximate to a boundary between the first fixed region and the free region and such that the ferromagnetic layer is narrower in a second portion proximate to a boundary between the second fixed region and the free region.

According to yet another aspect of the disclosure, a magnetic tunnel junction (MTJ) having a first fixed region, a second fixed region, and a free region coupled between the first fixed region and the second fixed region includes a ferromagnetic layer spanning the first fixed region, the second fixed region, and the free region. The MTJ also includes means for pinning domain walls in a first portion of the ferromagnetic layer proximate to a boundary between the first fixed region and the free region and in a second portion of the ferromagnetic layer proximate to a boundary between the second fixed region and the free region.

The foregoing has outlined rather broadly the features and technical advantages of the present invention in order that the detailed description that follows may be better understood. Additional features and advantages will be described hereinafter which form the subject of the claims of the invention. It should be appreciated by those skilled in the art that the conception and specific embodiments disclosed may be readily utilized as a basis for modifying or designing other structures for carrying out the same purposes of the present invention. It should also be realized by those skilled in the art that such equivalent constructions do not depart from the technology of the invention as set forth in the appended claims. The novel features which are believed to be characteristic of the invention, both as to its organization and method of operation, together with further objects and advantages will be better understood from the following description when considered in connection with the accompanying figures. It is to be expressly understood, however, that each of the figures is provided for the purpose of illustration and description only and is not intended as a definition of the limits of the present invention.

### BRIEF DESCRIPTION OF THE DRAWINGS

For a more complete understanding of the present invention, reference is now made to the following description taken in conjunction with the accompanying drawings.

FIG. 1A is a schematic illustrating a conventional cell of a magnetic random access memory device.

FIG. 1B is a cross-sectional view illustrating a conventional cell of a magnetic random access memory device in a “1” state.

FIG. 1C is a cross-sectional view illustrating a conventional cell of a magnetic random access memory device in a “0” state.

FIG. 2 is a cross-sectional view illustrating a conventional cell of a magnetic random access memory device with a domain wall dividing the cell.

FIG. 3A is a top-down view illustrating a layout pattern for patterning a ferromagnetic layer of an exemplary cell of a magnetic random access memory device according to a first embodiment.

FIG. 3B is a top-down view illustrating an exemplary cell of a magnetic random access memory device according to the first embodiment.

FIG. 4A is a top-down view illustrating a layout pattern for patterning a ferromagnetic layer of an exemplary cell of a magnetic random access memory device according to a second embodiment.

FIG. 4B is a top-down view illustrating an exemplary cell of a magnetic random access memory device according to the second embodiment.

FIG. 5A is a top-down view illustrating a layout pattern with scatter bars for patterning a ferromagnetic layer of an exemplary cell of a magnetic random access memory device according to a third embodiment.

FIG. 5B is a top-down view illustrating an exemplary cell of a magnetic random access memory device according to the third embodiment.

FIG. 6 is a top-down view illustrating an exemplary cell of a magnetic random access memory device according to a fourth embodiment.

FIG. 7 is a top-down view illustrating an exemplary cell of a magnetic random access memory device according to a fifth embodiment.

FIG. 8A is a top-down view illustrating a layout pattern with scatter bars for patterning a ferromagnetic layer of an exemplary cell of a magnetic random access memory device according to a sixth embodiment.

FIG. 8B is a top-down view illustrating an exemplary cell of a magnetic random access memory device according to the sixth embodiment.

FIG. 9 is a block diagram illustrating an exemplary wireless communication system in which an embodiment of the disclosure may be advantageously employed.

FIG. 10 is a block diagram illustrating a design workstation used for circuit, layout, and logic design of a magnetic random access memory device as disclosed below.

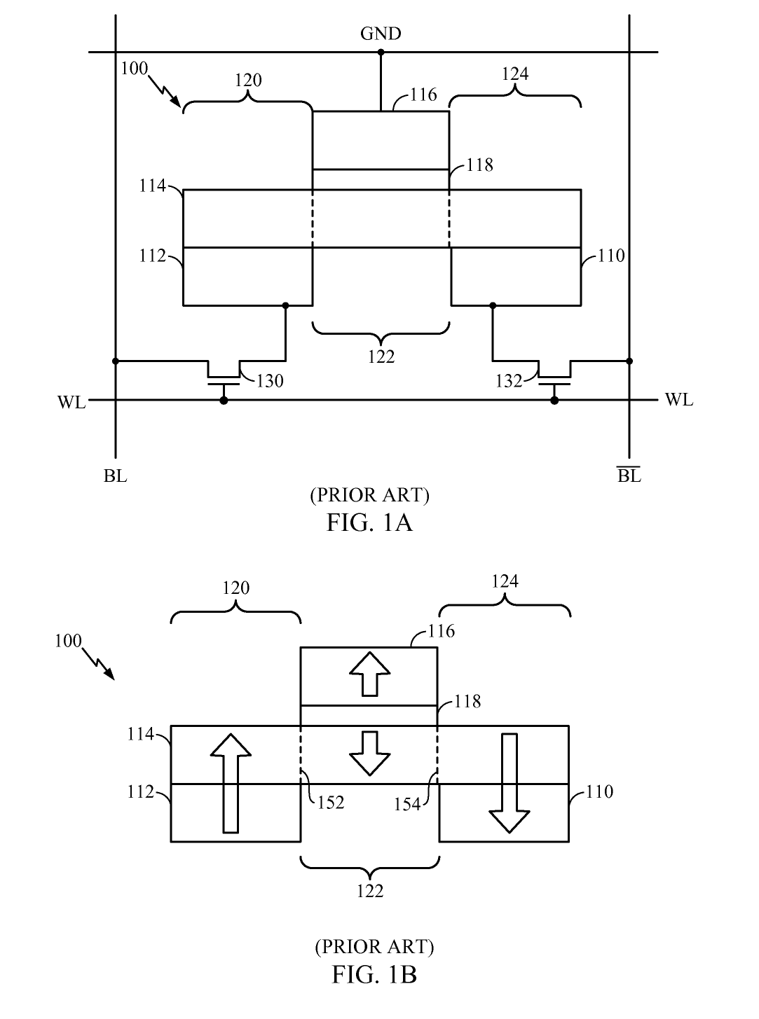

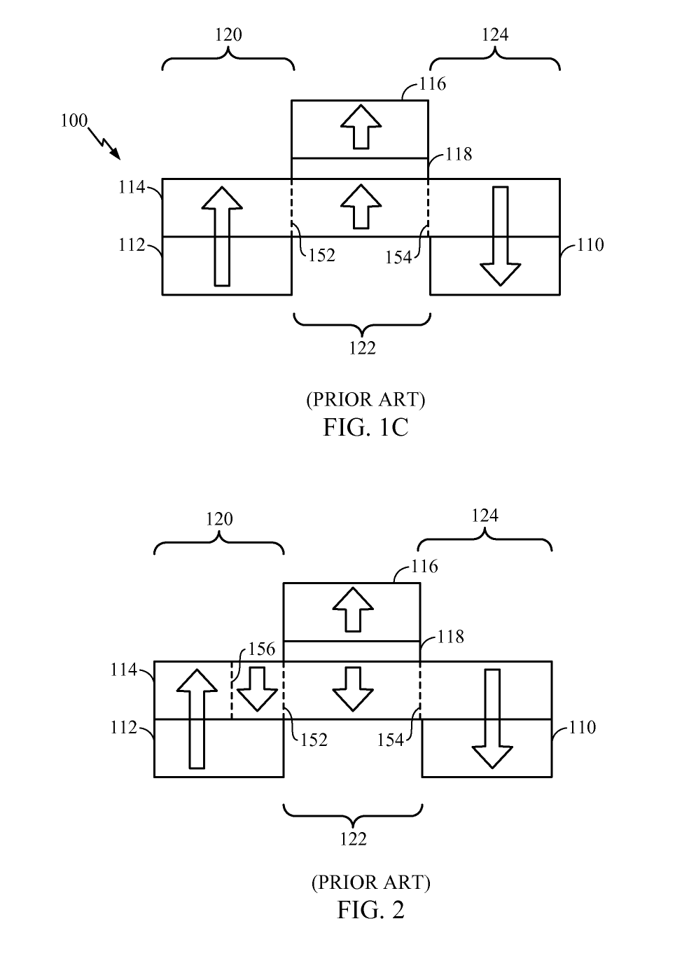

### DETAILED DESCRIPTION

Reliability of MRAM cells may be improved by creating pinning sites for the domain walls. Pinning sites in a ferromagnetic layer of an MRAM cell create an energy barrier for motion of the domain wall. The energy barrier substantially prevents the domain wall from moving beyond a free region of the ferromagnetic layer into a fixed region of the ferromagnetic layer for expected operating currents of the MRAM cell. The energy barrier also substantially prevents the domain wall from moving beyond the boundary of the free region and the fixed region back into a free region. Artificial pinning sites may be created by altering or adding mask patterns of a photomask that patterns the ferromagnetic layer.

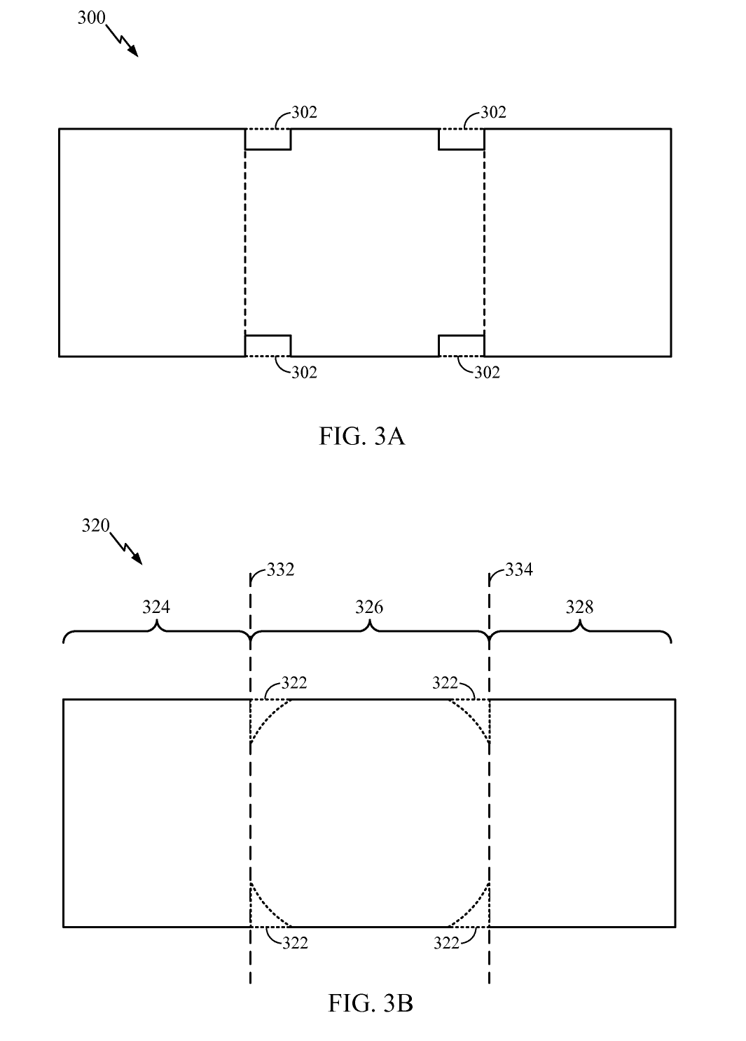

According to a first embodiment, a layout pattern 300 for patterning a ferromagnetic layer of an exemplary cell of a magnetic random access memory (MRAM) device includes features 302 (e.g., notches) as illustrated in FIG. 3A. The layout pattern 300 may be used to generate, for example, a photomask with notches, an optical proximity correction (OPC) photomask, a photomask with scatter bars, or a phase shift photomask. In embodiments in which a photomask with notches is generated a layout may be generated at either design or tape-out. In embodiments in which an OPC photomask is generated, the OPC photomask is generated at a foundry during the fabrication process. In embodiments in which a photomask with scatter bars are generated, the scatter bars are added at either design or tape-out. In embodiments in which a phase shift photomask is generated, the phase shift photomask is generated at a foundry.

A ferromagnetic layer 320 patterned with the layout pattern 300, is illustrated in FIG. 3B. The ferromagnetic layer 320 includes fixed regions 324, 328 and a free region 326. The fixed regions 324, 328 of the ferromagnetic layer 320 may have a fixed magnetization by coupling the fixed regions 324, 328 of the ferromagnetic layer 320 to a pinning layer (not shown). Additionally, the free region 326 of the ferromagnetic layer 320 may be coupled to a tunneling layer and reference layer (not shown) for use during sensing operations. According to one embodiment, the ferromagnetic layer 320 is magnetized perpendicular to the plane of the ferromagnetic layer 320.

After patterning of the ferromagnetic layer 320 with the layout pattern 300, the features 302 of the layout pattern 300 are substantially replicated as features 322 (e.g., rounding) of the ferromagnetic layer 320 in the proximity of a boundary 332 between the fixed region 324 of the ferromagnetic layer 320 and the free region 326 of the ferromagnetic layer 320 and a boundary 334 between the fixed region 328 of the ferromagnetic layer 320 and the free region 326 of the ferromagnetic layer 320. The narrow portion of the ferromagnetic layer 320 near the features 322 of the free region 326 of the ferromagnetic layer 320 creates an energy barrier for motion of a domain wall in the ferromagnetic layer 320.

The energy barrier reduces likelihood of a domain wall passing from the free region 326 of the ferromagnetic layer 320 into the fixed regions 324, 328 of the ferromagnetic layer 320 and reduces likelihood of a domain wall remaining in the free region 326 of the ferromagnetic layer 320 during write operations. Thus, the features 322 may be referred to as artificial pinning sites. The energy barrier also prevents disturbance of the cell during read operations by increasing the energy for switching the free region 326 of the ferromagnetic layer 320 from a “0” to “1” or a “1” to “0.” The energy barrier created by the features 322 is larger than energy barriers created by any imperfections of the ferromagnetic layer 320 during manufacturing of an MTJ cell. Thus, an MTJ cell having the ferromagnetic layer 320 has improved reliability and sensitivity.

According to one embodiment, pinning of the domain wall in the ferromagnetic layer 320 allows construction of an MTJ cell without pinning layers. The energy barriers resulting from the features 322 of the free region 326 creates a location for relaxation of the domain wall. That is, if during a write process the domain wall is pushed into the fixed regions 324, 328 the domain wall falls back to the energy barrier near the features 322 of the free region 326 after write current is turned off.

In an embodiment having no pinning layers, the fixed regions 324, 328 are set during fabrication by patterning the fixed region 324, setting the magnetization of the fixed region 324, patterning the fixed region 328, and setting the magnetization of the fixed region 328. In an embodiment having pinning layers, the fixed regions 324, 328 are fixed in magnetization by pinning layers (not shown) having anti-ferromagnetic materials. In another embodiment having pinning layers, the fixed regions 324, 328 are fixed in magnetization by pinning layers (not shown) having ferromagnetic materials exchange coupled to the fixed regions 324, 328. In some embodiments, the pinning layers (not shown) are the same ferromagnetic materials used in the fixed regions 324, 328.

Patterning of the ferromagnetic layer 320 may be carried out in one embodiment by depositing a photoresist (not shown) on the ferromagnetic layer 320. The photoresist is exposed through a photomask generated from the layout pattern 300 to generate exposure patterns in the photoresist. The photoresist is placed in a developer to wash away regions of photoresist in the exposure pattern. The ferromagnetic layer 320 may be patterned using the photoresist as a hard mask during a wet and/or dry etch. The pinning sites are created during patterning of the ferromagnetic layer 320 in the manufacturing process for an MTJ such that no additional processes are added for creating the pinning sites. According to one embodiment, a reference layer (not shown) coupled to the ferromagnetic layer 320 is patterned to match substantially the features 322 of the free region 326. In other embodiments, the reference layer is not patterned to match the features 322 of the free region 326.

Although only one MTJ cell is illustrated in FIG. 3B, many may be patterned and manufactured in parallel through the process described above. The photomask may include multiple copies of the layout pattern 300. According to one embodiment, the layout pattern 300 is placed in direct contact with a neighboring layout pattern such that the pattern is a continuous bar with multiple features 322.

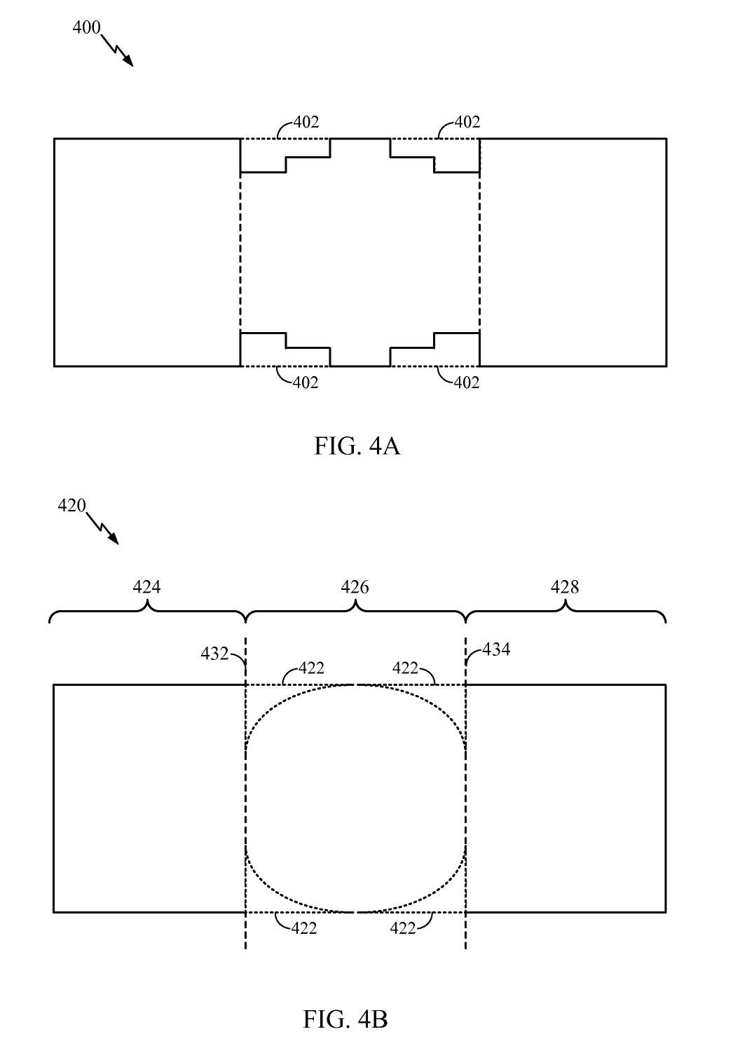

According to a second embodiment, a layout pattern 400 for patterning a ferromagnetic layer of an exemplary cell of an MRAM device includes features 402 (e.g., larger notches) illustrated in FIG. 4B. A ferromagnetic layer 420 patterned with the layout pattern 400 is illustrated in FIG. 4B. The ferromagnetic layer 420 includes fixed regions 424, 428 and a free region 426.

After patterning the ferromagnetic layer 420 with the layout pattern 400 the features 402 of the layout pattern 400 are substantially replicated as features 422 (e.g., rounding) of the ferromagnetic layer 420 in the proximity of a boundary 432 between the fixed region 424 of the ferromagnetic layer 420 and the free region 426 of the ferromagnetic layer 420 and in the proximity of a boundary 434 between the fixed region 428 of the ferromagnetic layer 420 and the free region 426 of the ferromagnetic layer 420. The narrow portion of the ferromagnetic layer 420 near the features 422 of the free region 426 of the ferromagnetic layer 420 creates an energy barrier for motion of a domain wall in the ferromagnetic layer 420. The energy barrier reduces likelihood of a domain wall passing from the free region 426 into the fixed regions 424, 428 during write operations and prevents a domain wall from remaining in the free region 426 of the ferromagnetic layer 420.

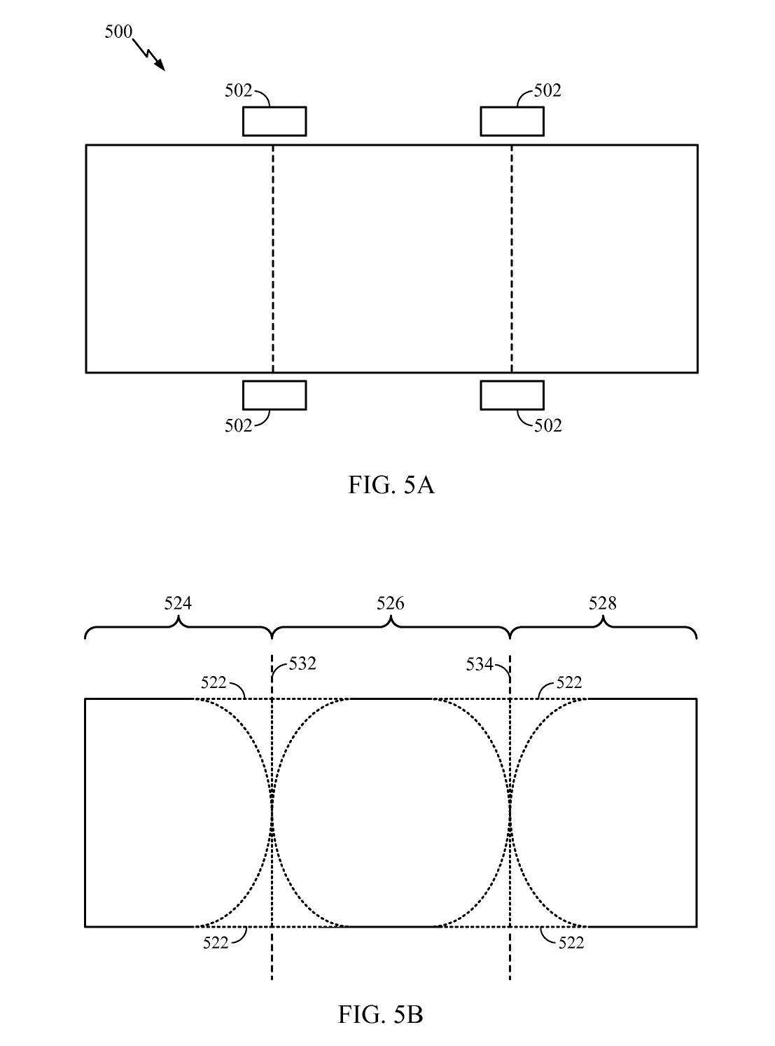

According to a third embodiment, a layout pattern 500 with features 502 (e.g., scatter bars) for patterning a ferromagnetic layer of an exemplary cell of an MRAM device is illustrated in FIG. 5A. A ferromagnetic layer 520 patterned with the layout pattern 500 is illustrated in FIG. 5B. The ferromagnetic layer 520 includes fixed regions 524, 528 and a free region 526.

After patterning the ferromagnetic layer 520 with the layout pattern 500 the features 502 of the layout pattern 500 are substantially replicated as features 522 (e.g., rounding) of the ferromagnetic layer 520 in the proximity of a boundary 532 between the fixed region 524 of the ferromagnetic layer 520 and the free region 526 of the ferromagnetic layer 520 and in the proximity of a boundary 534 between the fixed region 528 of the ferromagnetic layer 520 and the free region 526 of the ferromagnetic layer 520. The narrow portion of the ferromagnetic layer 520 near the features 522 of the free region 526 of the ferromagnetic layer 520 creates an energy barrier for the motion of a domain wall in the ferromagnetic layer 520. The energy barrier reduces likelihood of a domain wall passing from the free region 526 of the ferromagnetic layer 520 into the fixed regions 524, 528 of the ferromagnetic layer 520 and prevents a domain wall from remaining in the free region 526 of the ferromagnetic layer 520 during write operations.

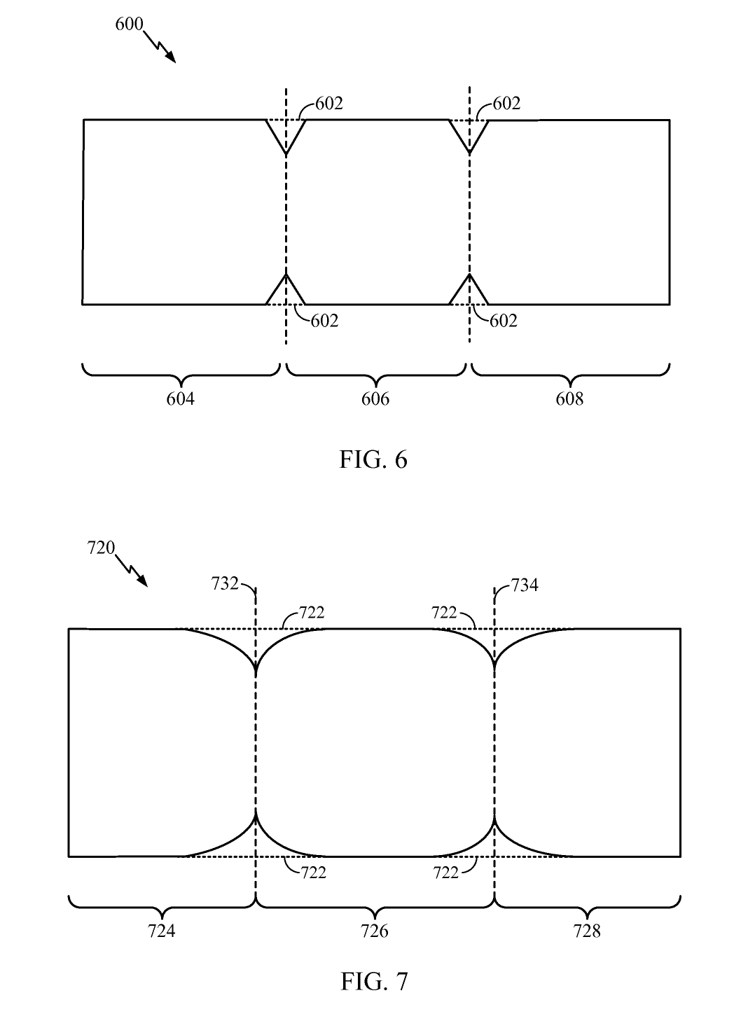

According to a fourth embodiment, a ferromagnetic layer 600 patterned with features 602 (e.g., rounding) is illustrated in FIG. 6. The features 602 may be generated as a result of a photomask (not shown) used during lithographic exposure. The photomask for generating features 602 may be a photomask with notches, an OPC photomask, a phase shift photomask, or a photomask with scatter bars. The ferromagnetic layer 600 includes fixed regions 604, 608 and a free region 606. The narrow portion of the ferromagnetic layer 600 near the features 602 of the free region 606 creates an energy barrier for motion of a domain wall in the ferromagnetic layer 600. The energy barrier reduces likelihood of a domain wall passing from the free region 606 into the fixed regions 604, 608 and prevents a domain wall from remaining in the free region 606 of the ferromagnetic layer 600 during write operations.

Similarly, according to a fifth embodiment, a ferromagnetic layer 720 patterned with features 722 (e.g., rounding) is illustrated in FIG. 7. The features 722 may be generated as a result of a photomask (not shown) used during lithographic exposure. The photomask for generating features 722 may be a photomask with notches, an OPC photomask, a phase shift photomask, or a photomask with scatter bars. The ferromagnetic layer 720 includes fixed regions 724, 728 and a free region 726. The narrow portion of the ferromagnetic layer 720 near the features 722 of the free region 726 creates an energy barrier for motion of a domain wall in the ferromagnetic layer 720. The energy barrier reduces likelihood of a domain wall passing from the free region 726 into the fixed regions 724, 728 and prevents a domain wall from remaining in the free region 726 of the ferromagnetic layer 720 during write operations.

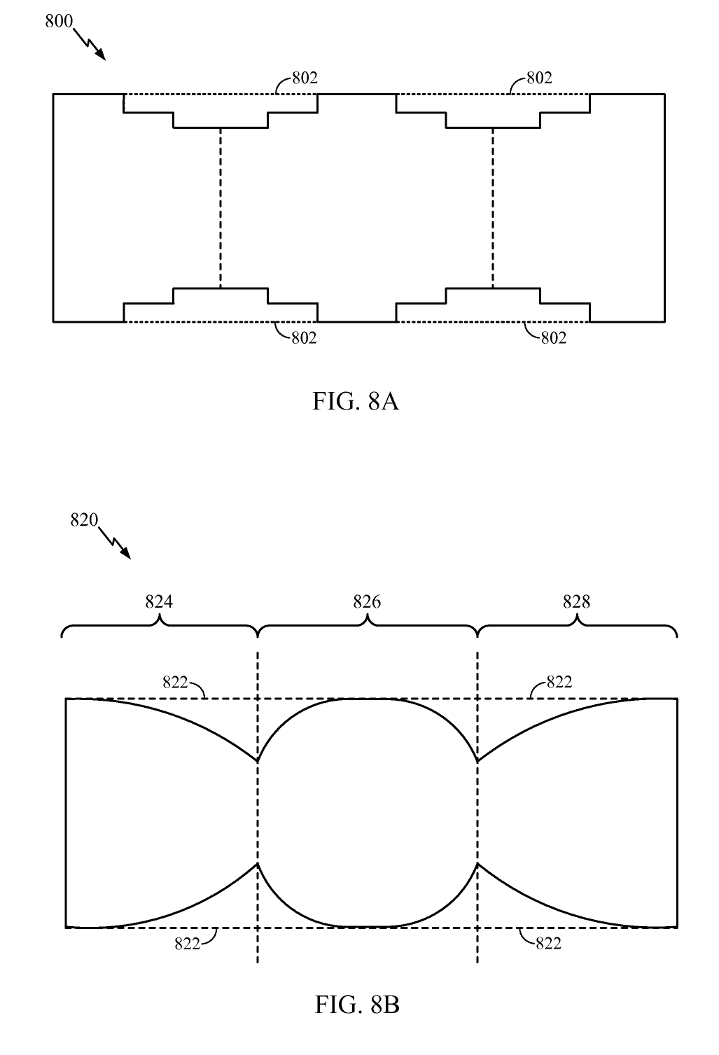

According to a sixth embodiment, a mask pattern 800 with features 802 (e.g., notches) for patterning a ferromagnetic layer of an exemplary cell of an MRAM device is illustrated in FIG. 8A. A ferromagnetic layer 820 patterned with the mask pattern 800 is illustrated in FIG. 8B. The ferromagnetic layer 820 includes fixed regions 824, 828 and a free region 826.

After patterning the ferromagnetic layer 820 with the mask pattern 800 the features 802 of the mask pattern 800 are substantially replicated as features 822 (e.g., rounding) of the ferromagnetic layer 820 in the proximity of a boundary 832 between the fixed region 824 of the ferromagnetic layer 820 and the free region 826 of the ferromagnetic layer 820 and in the proximity of a boundary 834 between the fixed region 828 of the ferromagnetic layer 820 and the free region 826 of the ferromagnetic layer 820. According to this embodiment, the features 802 extend into the free region 826 and the fixed regions 824, 828. The narrow portion of the ferromagnetic layer 820 near the features 822 of the free region 826 of the ferromagnetic layer 820 creates an energy barrier for the motion of a domain wall in the ferromagnetic layer 820. The energy barrier reduces likelihood of a domain wall passing from the free region 826 of the ferromagnetic layer 820 into the fixed regions 824, 828 of the ferromagnetic layer 820 and prevents a domain wall from remaining in the free region 826 of the ferromagnetic layer 820 during write operations.

Magnetic tunnel junction (MTJ) devices with pinning sites for domain walls have improved reliability and sensitivity. The pinning sites create energy barriers, which substantially prevent a domain wall in the free regions of the MTJ from entering fixed regions of the MTJ. The pinning sites may be narrow portions of a ferromagnetic layer. The narrow portions may be patterned using features on a photomask, including notches, scatter bars, and phase shifts. In some embodiments of the MTJ, the ferromagnetic layer is magnetized in a direction perpendicular to the plane of the ferromagnetic layer.

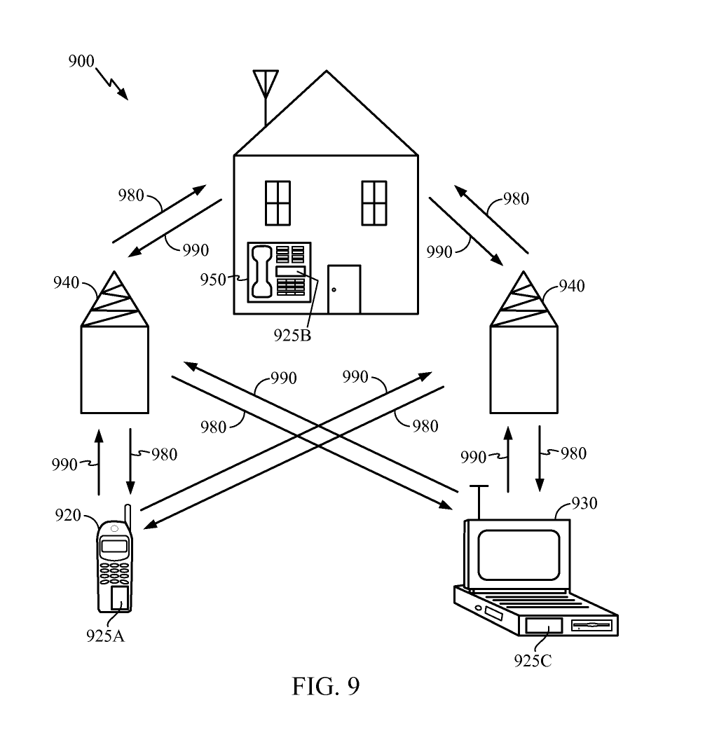

FIG. 9 shows an exemplary wireless communication system 900 in which an embodiment of the disclosure may be advantageously employed. For purposes of illustration, FIG. 9 shows three remote units 920, 930, and 950 and two base stations 940. It will be recognized that wireless communication systems may have many more remote units and base stations. Remote units 920, 930, and 950 include MRAM devices 925A, 925C, and 925B, respectively, having magnetic tunneling junctions which are embodiments as discussed above. FIG. 9 shows forward link signals 980 from the base stations 940 and the remote units 920, 930, and 950 and reverse link signals 990 from the remote units 920, 930, and 950 to base stations 940.

In FIG. 9, remote unit 920 is shown as a mobile telephone, remote unit 930 is shown as a portable computer, and remote unit 950 is shown as a computer in a wireless local loop system. For example, the remote units may be cell phones, hand-held personal communication systems (PCS) units, portable data units such as personal data assistants, or fixed location data units such as meter reading equipment. Although FIG. 9 illustrates remote units according to the teachings of the disclosure, the disclosure is not limited to these exemplary illustrated units. The disclosure may be suitably employed in any device which includes MRAM devices having magnetic tunnel junctions.

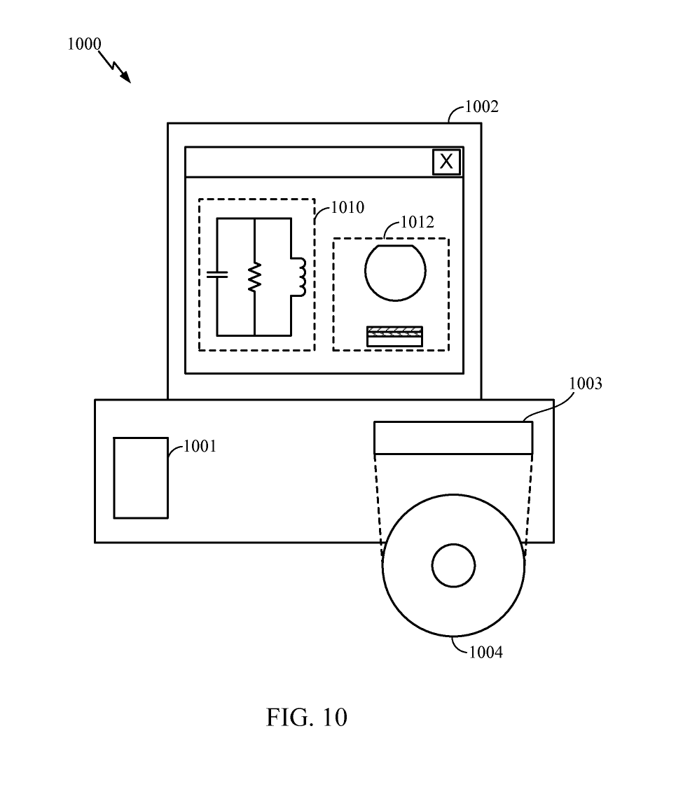

FIG. 10 is a block diagram illustrating a design workstation used for circuit, layout, and logic design of an MRAM device, as disclosed above. A design workstation 1000 includes a hard disk 1001 containing operating system software, support files, and design software such as Cadence or OrCAD. The design workstation 1000 also includes a display to facilitate design of a circuit 1010 or an MRAM component 1012. A storage medium 1004 is provided for tangibly storing the circuit design 1010 or the MRAM component 1012. The circuit design 1010 or the MRAM component 1012 may be stored on the storage medium 1004 in a file format such as GDSII or GERBER. The storage medium 1004 may be a CD-ROM, DVD, hard disk, flash memory, or other appropriate device. Furthermore, the design workstation 1000 includes a drive apparatus 1003 for accepting input from or writing output to the storage medium 1004.

Data recorded on the storage medium 1004 may specify logic circuit configurations, pattern data for photolithography masks including features as described in FIGS. 3A, 4A, 5A, 6A, and 8A or mask pattern data for serial write tools such as electron beam lithography. The data may further include logic verification data such as timing diagrams or net circuits associated with logic simulations. Providing data on the storage medium 1004 facilitates the design of the circuit design 1010 or the MRAM component 1012 by decreasing the number of processes for designing semiconductor wafers.

The methodologies described herein may be implemented by various components depending upon the application. For example, these methodologies may be implemented in hardware, firmware, software, or any combination thereof. For a hardware implementation, the processing units may be implemented within one or more application specific integrated circuits (ASICs), digital signal processors (DSPs), digital signal processing devices (DSPDs), programmable logic devices (PLDs), field programmable gate arrays (FPGAs), processors, controllers, micro-controllers, microprocessors, electronic devices, other electronic units designed to perform the functions described herein, or a combination thereof.

For a firmware and/or software implementation, the methodologies may be implemented with modules (e.g., procedures, functions, and so on) that perform the functions described herein. Any machine-readable medium tangibly embodying instructions may be used in implementing the methodologies described herein. For example, software codes may be stored in a memory and executed by a processor unit. Memory may be implemented within the processor unit or external to the processor unit. As used herein the term “memory” refers to any type of long term, short term, volatile, nonvolatile, or other memory and is not to be limited to any particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be any available medium that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to store desired program code in the form of instructions or data structures and that can be accessed by a computer; disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

In addition to storage on computer readable medium, instructions and/or data may be provided as signals on transmission media included in a communication apparatus. For example, a communication apparatus may include a transceiver having signals indicative of instructions and data. The instructions and data are configured to cause one or more processors to implement the functions outlined in the claims.

Although the present invention and its advantages have been described in detail, it should be understood that various changes, substitutions and alterations can be made herein without departing from the technology of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A magnetic tunnel junction (MTJ) device, comprising:
a first fixed region of a ferromagnetic layer;
a second fixed region of the ferromagnetic layer;
a free region of the ferromagnetic layer between the first fixed region of the ferromagnetic layer and the second fixed region of the ferromagnetic layer; and
at least one feature in proximity to a first boundary between the first fixed region of the ferromagnetic layer and the free region of the ferromagnetic layer and at least one feature in proximity to a second boundary between the second fixed region of the ferromagnetic layer and the free region of the ferromagnetic layer, in which the features act as artificial pinning sites for domain walls.

2. The MTJ of claim 1, in which the features comprise notches in the ferromagnetic layer.

3. The MTJ of claim 2, in which the notches are within the free region of the ferromagnetic layer.

4. The MTJ of claim 3, in which the notches are within the first and second fixed regions of the ferromagnetic layer.

5. The MTJ of claim 1, further comprising:
a first pinning layer coupled to the ferromagnetic layer in the first fixed region; and
a second pinning layer coupled to the ferromagnetic layer in the second fixed region.

6. The MTJ of claim 1, in which the ferromagnetic layer is magnetized perpendicularly.

7. The MTJ of claim 1, further comprising a magnetic random access memory (MRAM) device into which the MTJ is integrated.

8. The MTJ of claim 1, integrated into at least one of a set top box, music player, video player, entertainment unit, navigation device, communications device, personal digital assistant (PDA), fixed location data unit, and a computer.

9. A method of manufacturing a magnetic tunnel junction (MTJ) having a first fixed region, a second fixed region, and a free region coupled between the first fixed region and the second fixed region, the method comprising:
patterning a ferromagnetic layer of the MTJ such that the ferromagnetic layer is narrower in a first portion proximate to a boundary between the first fixed region and the free region and such that the ferromagnetic layer is narrower in a second portion proximate to a boundary between the second fixed region and the free region.

10. The method of claim 9, in which patterning the ferromagnetic layer comprises:
depositing a photoresist on the ferromagnetic layer;
exposing the photoresist through a photomask having exposure patterns;
developing the exposure patterns in the photoresist; and
etching the ferromagnetic layer after developing the photoresist;

11. The method of claim 10, in which the exposure patterns have narrow regions.

12. The method of claim 10, in which the photomask comprises at least one of a photomask with notches, a photomask with scatter bars, a phase shift photomask, and an optical proximity correction photomask.

13. The method of claim 9, further comprising integrating the MTJ in at least one of a set top box, music player, video player, entertainment unit, navigation device, communications device, personal digital assistant (PDA), fixed location data unit, and a computer.

14. A method of manufacturing a magnetic tunnel junction (MTJ) having a first fixed region, a second fixed region, and a free region coupled between the first fixed region and the second fixed region, the method comprising the step of:
patterning a ferromagnetic layer of the MTJ such that the ferromagnetic layer is narrower in a first portion proximate to a boundary between the first fixed region and the free region and such that the ferromagnetic layer is narrower in a second portion proximate to a boundary between the second fixed region and the free region.

15. The method of claim 14, in which the step of patterning the ferromagnetic layer comprises the steps of:
depositing a photoresist on the ferromagnetic layer;
exposing the photoresist through a photomask having exposure patterns;
developing the exposure patterns in the photoresist; and
etching the ferromagnetic layer after developing the photoresist;

16. The method of claim 15, in which the exposure patterns have narrow regions.

17. The method of claim 15, in which the exposure patterns have scatter bars.

18. The method of claim 14, further comprising the step of integrating the MTJ in at least one of a set top box, music player, video player, entertainment unit, navigation device, communications device, personal digital assistant (PDA), fixed location data unit, and a computer.

19. A magnetic tunnel junction (MTJ) having a first fixed region, a second fixed region, and a free region coupled between the first fixed region and the second fixed region, the MTJ comprising:
a ferromagnetic layer spanning the first fixed region, the second fixed region, and the free region; and
means for pinning domain walls in a first portion of the ferromagnetic layer proximate to a boundary between the first fixed region and the free region and in a second portion of the ferromagnetic layer proximate to a boundary between the second fixed region and the free region.

20. The MTJ of claim 19, in which the MTJ is integrated into at least one of a set top box, music player, video player, entertainment unit, navigation device, communications device, personal digital assistant (PDA), fixed location data unit, and a computer.
